(19) United States
(12) Patent Application Publication
(10) Pub. No.: US 2012/0067274 A1
(43) Pub. Date: Mar. 22, 2012

(54) FILM FORMING APPARATUS, WAFER HOLDER, AND FILM FORMING METHOD

(75) Inventors: Daisuke HARA, Toyama (JP); Kazuhiro SHIMURA, Toyama (JP); Masaki MUROBAYASHI, Toyama (JP); Yukitomo HIROCHI, Toyama (JP)

(73) Assignee: HITACHI KOKUSAI ELECTRIC INC., Tokyo (JP)

(21) Appl. No.: 13/036,304

(22) Filed: Feb. 28, 2011

(30) Foreign Application Priority Data
Sep. 22, 2010 (JP) 2010-211878

(51) Int. Cl. C30B 25/02; C23C 16/458; C23C 16/455

(52) U.S. Cl. 117/88; 118/728

(57) ABSTRACT

A wafer holder used in a film forming apparatus is disclosed. The wafer holder including a boat holding a plurality of wafers and a reaction gas supply part supplying a reaction gas from a side surface of the plurality of wafers held by the boat, and the wafer holder further includes an upper wafer holder being placed to cover an upper surface of each of the plurality of wafers when the plurality of wafer is supported by the boat and including a gas introduction suppression part suppressing an introduction of the reaction gas onto the upper surface of each the plurality of wafers by surrounding each of the plurality of wafers.

### CROSS-REFERENCE TO RELATED PATENT APPLICATION

This application claims priority to and the benefit of Japanese Patent Application No. 2010-211878 filed on Sep. 22, 2010, the disclosure of which is incorporated herein by reference.

### FIELD OF THE INVENTION

The present invention relates to a film forming apparatus and a wafer holder used in the film forming apparatus, and further, a film forming method using the film forming apparatus, and more particularly, to a film forming apparatus for forming a silicon carbide (hereinafter, referred to as “SiC”) epitaxial layer on a substrate, a wafer holder, and a film forming method.

### DESCRIPTION OF THE RELATED ART

An example of such a film forming apparatus includes a vacuum film forming apparatus disclosed in Patent Document 1. According to Patent Document 1, in order to solve problems such as deposits of a source gas sticking to a surface opposite to a susceptor and instability of SiC epitaxial growth due to generation of convection of the source gas, a vacuum film forming apparatus in which a surface for holding a substrate of the susceptor is directed downward and a thin film forming method are disclosed.

In addition, as a high temperature chemical vapor deposition (CVD) apparatus for heating a susceptor in a reaction chamber to a high temperature through a radio frequency induction heating method, a batch-type vertical high temperature CVD apparatus in which film-forming surfaces of a plurality of substrates are directed downward, preventing dust from being stuck to the film-forming surfaces is disclosed (for example, see Patent Document 2).

### PRIOR ART DOCUMENTS

### Patent Documents

1. Japanese Patent Laid-open Publication No.: 2006-196807

2. Japanese Patent Laid-open Publication No.: 2003-100643

However, in the batch-type vertical film forming apparatus of Patent Document 2 of the conventional art, a gap may occur between a back surface of the substrate and the susceptor to introduce a process gas supplied in a horizontal direction onto the back surface of the substrate, forming a film on the back surface of the substrate, which may be inherently unnecessary. Here, since the film must be removed through an polishing process, etc., manufacturing processes are lengthened, which decreases throughput. In particular, since SiC is a hard material and polishing process of SiC takes much time, it is difficult to improve throughput of the film forming process.

### SUMMARY OF THE INVENTION

In order to solve the problems, it is an object of the present invention to provide a wafer holder capable of improving throughput of a film forming process even in a batch-type vertical film forming apparatus, a film forming apparatus on which the wafer holder is mounted, and a film forming method.

According to an aspect of the present invention, there is provided a wafer holder used in a film forming apparatus including a boat holding a plurality of wafers and a reaction gas supply part supplying a reaction gas from side surfaces of the plurality of wafers held by the boat, the wafer holder including: an upper wafer holder placed to cover an upper surface of each of the plurality of wafers when the plurality of wafer is supported by the boat and including a gas introduction suppression part suppressing an introduction of the reaction gas onto the upper surface of each the plurality of wafers by surrounding each of the plurality of wafers, or a film forming apparatus on which the wafer holder is mounted.

According to another aspect of the present invention, there is provided a film forming method including: placing an upper wafer holder to cover an upper surface of a wafer, the upper wafer holder having a gas introduction suppression part suppressing an introduction of a reaction gas onto an upper surface of a wafer by surrounding the wafer; transferring the wafer and the upper wafer holder to a boat with the upper wafer holder placed on the wafer; loading the boat into a reaction chamber; and supplying the reaction gas into the reaction chamber to form a film on a lower surface of the wafer.

According to the present invention, a film forming apparatus, a wafer holder, and a film forming method, which are capable of improving throughput of a film forming process, may be provided.

### BRIEF DESCRIPTION OF THE DRAWINGS

FIG. 1 is a perspective view illustrating a configuration of a SiC film forming apparatus in accordance with a first embodiment of the present invention;

FIG. 2 is a side cross-sectional view of a processing furnace of the SiC film forming apparatus in accordance with the first embodiment of the present invention;

FIG. 3 is an enlarged view of a wafer and a wafer holder in accordance with the first embodiment of the present invention;

FIG. 4 is an exploded perspective view illustrating a configuration of a wafer and a wafer holder in accordance with a second embodiment of the present invention;

FIG. 5 is an enlarged view of the wafer and the wafer holder in accordance with the second embodiment of the present invention;

FIG. 6 is an enlarged view of the wafer holder in accordance with the second embodiment of the present invention; and

FIG. 7 is an enlarged view of a wafer and a wafer holder in accordance with a third embodiment of the present invention.

### DETAILED DESCRIPTION OF THE PREFERRED EMBODIMENTS

### First Embodiment

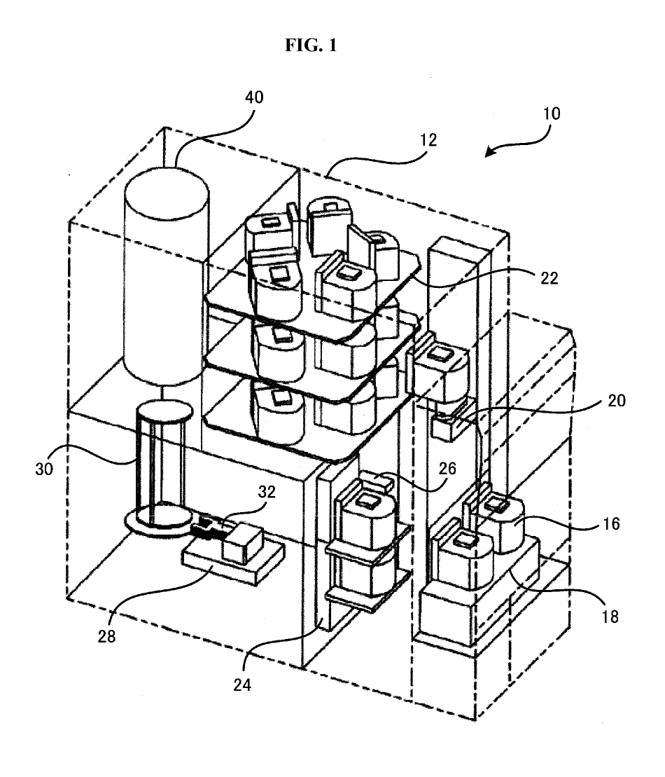

First, a configuration of a SiC film forming apparatus in accordance with the first embodiment of the present invention in which some operations thereof are included will be described with reference to FIGS. 1 to 3. Here, FIG. 1 is a perspective view showing the configuration of the SiC film forming apparatus in accordance with the first embodiment of the present invention.

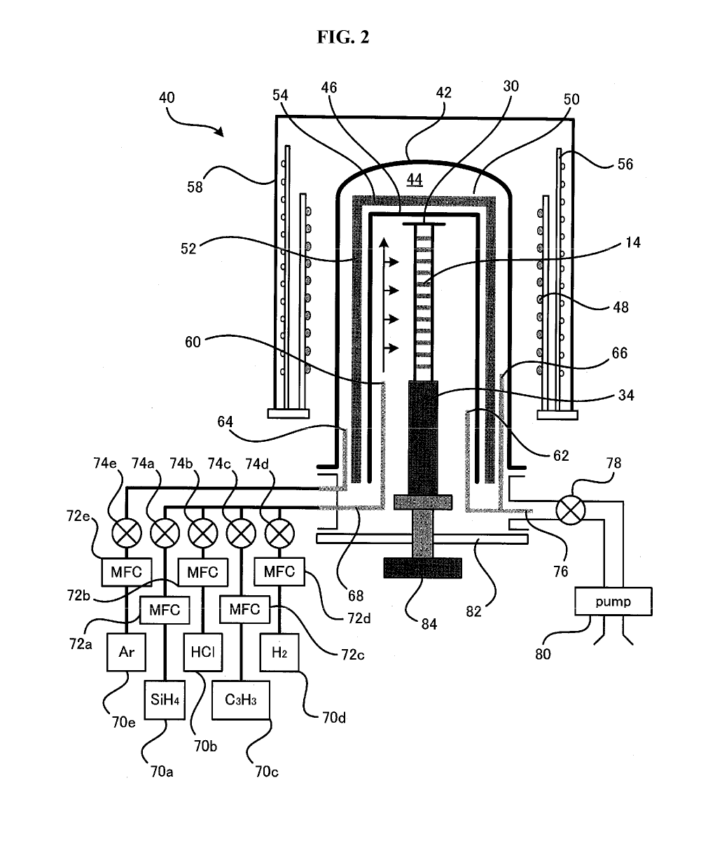

As the SiC film forming apparatus in accordance with the first embodiment of the present invention, a semiconductor manufacturing apparatus 10 is a batch-type vertical SiC film forming apparatus that includes a housing 12 in which major components are disposed. In the semiconductor manufacturing apparatus 10, a front opening unified pod 16 (FOUP, hereinafter, referred to as a “pod”) serving as a substrate accommodation unit for accommodating a wafer 14 (see FIG. 2) as a substrate made of Si, SiC, etc. is used as a wafer carrier. A pod stage 18 is disposed in the front of the housing 12, and the pod 16 is transferred to the pod stage 18. The pod 16 accommodates, for example, twenty five sheets of wafers 14, and is set to the pod stage 18 with its lid closed.

A pod transfer apparatus 20 is disposed in the front of the housing 12 and vertically opposite to the pod stage 18. In addition, a pod shelf 22, a pod opener 24, and a substrate number detector 26 are disposed adjacent to the pod transfer apparatus 20. The pod shelf 22 is disposed over the pod opener 24 and configured to hold the plurality of pods 16 placed thereon. The substrate number detector 26 is disposed adjacent to the pod opener 24. The pod transfer apparatus 20 transfers the pod 16 among the pod stage 18, the pod shelf 22 and the pod opener 24. The pod opener 24 functions to open the lid of the pod 16, and the substrate number detector 26 functions to detect the number of the wafers 14 in the pod 16 whose lid is open.

A substrate transfer unit 28 and a boat 30 as a substrate supporter are disposed in the housing 12. The substrate transfer unit 28 includes an arm (tweezers) 32, and is configured to be able to vertically rotate by a driving means (not shown). The arm 32 can take out five sheets of wafers, and the arm 32 is moved to transfer the wafers 14 between the pod 16, which is disposed at a position of the pod opener 24, and the boat 30.

The boat 30 is, for example, made of a heat resistant material such as carbon graphite or SiC, and configured to concentrically align the plurality of wafers 14 in a horizontal posture and hold the wafers 14 in a vertically stacked state. In addition, a boat insulating part 34 serving as an insulating member made of a heat resistant material such as carbon graphite, quartz or SiC and having a circular disc shape is disposed under the boat 30 such that heat from an object to be heated 46, which will be described later, cannot be easily transmitted to a lower side of a processing furnace 40 (see FIG. 2).

The processing furnace 40 is disposed at an upper part of a rear side in the housing 12. The boat 30 into which the plurality of wafers 14 are charged is loaded into the processing furnace 40 to perform heat treatment.

Next, referring to FIG. 2, a configuration of the processing furnace 40 in accordance with the first embodiment of the present invention will be described. FIG. 2 is a side cross-sectional view of the processing furnace 40 of the semiconductor manufacturing apparatus 10 in accordance with the first embodiment of the present invention.

The processing furnace 40 includes a reaction tube 42 having a cylindrical shaped reaction chamber 44 formed therein. The reaction tube 42 is made of a heat resistant material such as quartz and SiC, and has a cylindrical shape with its upper end closed and its lower end open. The reaction chamber 44 is formed in a tubular hollow part inside the reaction tube 42, and configured to receive the wafers 14 in a state in which the wafers 14 as substrates made of Si, SiC, etc., are concentrically aligned by the boat 30 in a horizontal posture via a wafer holder, which will be described later, to be vertically stacked and held.

A manifold is installed around a lower side of the reaction tube 42 in a concentric manner relative to the reaction tube 42. The manifold is made of stainless steel, etc., and has a cylindrical shape with its upper and lower ends open. The manifold is installed to support the reaction tube 42. In addition, an O-ring as a seal member is installed between the manifold and the reaction tube 42. As the manifold is supported by a retainer (not shown), the reaction tube 42 is vertically installed. The reaction tube 42 and the manifold constitute a reaction container.

The processing furnace 40 includes an object to be heated 46, and an induction heating source as a magnetic field generating part, for example, an induction coil 48. The object to be heated 46 is installed in the reaction chamber 44, and the object to be heated 46 is installed to surround an arrangement region of the wafers 14, which are at least substrates. The object to be heated 46 is configured to be heated by a magnetic field generated by the induction coil 48 installed outside the reaction tube 42. As the object to be heated 46 generates heat, an interior of the reaction chamber 44 is heated.

The object to be heated 46 has a cylindrical shape with one end (i.e., an upper side shown in the drawing) closed. As a result, a supplied gas may be sealed. In addition, heat radiation from an upper part of the reaction chamber 44 may be suppressed.

A temperature sensor (not shown) as a temperature detector for detecting a temperature in the reaction chamber 44 is installed adjacent to the object to be heated 46. A temperature control unit (not shown) is electrically connected to the induction coil 48 as an induction heating source and the temperature sensor, and configured to control the temperature in the reaction chamber 44 to reach a predetermined temperature distribution at predetermined timing by adjusting a conduction state to the induction coil 48 according to temperature information detected by the temperature sensor.

An insulating material 50 made of a carbon felt, etc., which cannot be easily induced, is installed between the object to be heated 46 and the reaction tube 42, and thus, transmission of heat of the object to be heated 46 to the reaction tube 42 or an outside of the reaction tube 42 can be suppressed by installing the insulating material 50.

As shown in FIG. 2, the insulating material 50 includes a cylindrical sidewall part 52, and a lid part 54 for closing one end (i.e., an upper side shown in the drawing) of the insulating material 50. Accordingly, the sidewall part 52 and the lid part 54 may define a hollow part installed inside the insulating material 50, and the object to be heated 46 may be installed therein to constitute a reaction furnace. In addition, the induction coil 48 inductively heats the object to be heated 46, and thus, affection of radiation heat from the object to be heated 46, which is generated when the wafers 14 as the substrates placed in the object to be heated 46 undergo a predetermined process, can be blocked by the insulating material 50. Further, the sidewall part 52 and the lid part 54 may be made of different members.

In addition, in order to suppress transfer of heat in the reaction chamber 44 to the outside, an outer insulating wall 56 of a water-cooling structure is installed to surround the reaction chamber 44. Further, a magnetic seal 58 is installed around the outer insulating wall 56 to prevent a magnetic field generated by the induction coil 48 from leaking to the outside.

As shown in FIG. 2, a first gas supply port 60 for supplying at least a silicon (Si) atom-containing gas, a chlorine (Cl) atom-containing gas, a carbon (C) atom-containing gas and a reduction gas, and a first exhaust port 62 are installed between the object to be heated 46 and the wafers 14, and a second gas supply port 64 and a second exhaust port 66 are disposed between the reaction tube 42 and the insulating material 50. Each component will be described below in detail.

The first gas supply port 60 for supplying at least a Si atom-containing gas such as monosilane (hereinafter, referred to as “SiH₄”), a Cl atom-containing gas such as hydrochloride (hereinafter, referred to as “HCl”), a C atom-containing gas such as propane (hereinafter, referred to as “C₃H₈”), and a reduction gas such as hydrogen (hereinafter, referred to as “H₂”) is made of, for example, carbon graphite, installed inside the object to be heated 46 and adjacent to a side part of the wafers 14, and installed in the manifold to pass through the manifold.

The gas supply port 60 is connected to a first gas line 68. The first gas line 68 is connected to, for example, a SiH₄ gas source 71a, a HCl gas source 70b, a C₃H₈ gas source 70c and a H₂ gas source 70d via mass flow controllers (hereinafter, referred to as “MFCs”) 72a, 72b, 72c and 72d and valves 74a, 74b, 74c and 74d as flow rate controllers (flow rate control means) with respect to, for example, a SiH₄ gas, a HCl gas, a C₃H₈ gas and a H₂ gas, respectively.

According to the above configuration, for example, flow rates, concentrations and partial pressures of the SiH₄, HCl, C₃H₈ and H₂ gases can be controlled in the reaction chamber 44, respectively. The valves 74a, 74b, 74c and 74d and the MFCs 72a, 72b, 72c and 72d are electrically connected to each other by a gas flow rate control unit (not shown), and controlled such that the flow rates of the supplied gases become predetermined flow rates at predetermined timings. Here, the gas sources 70a, 70b, 70c and 70d of the SiH₄, HCl, C₃H₈ and H₂ gases, the valves 74a, 74b, 74c and 74d, the MFCs 72a, 72b, 72c and 72d, the first gas line 68 and the first gas supply port 60 constitute a first gas supply system as a gas supply system.

In addition, as described above, while the gas supply port 60 is installed to supply at least the Si atom-containing gas, the Cl atom-containing gas, the C atom-containing gas and the reduction gas, the gas supply port is not limited thereto but may be installed to correspond to each of the gases, or may be installed to supply mixed gases.

Further, while the HCl gas is exemplified as the Cl atom-containing gas, chlorine (Cl₂) gas may be used.

Furthermore, as described above, while the Si atom-containing gas and the Cl atom-containing gas are supplied, a gas containing Si atoms and Cl atoms, for example, tetrachlorosilane (hereinafter, referred to as “SiCl₄”) gas, trichlorosilane (hereinafter, referred to as “SiHCl₃”) gas and dichlorosilane (hereinafter, referred to as “SiH₂Cl₂”) gas may be supplied.

In addition, while the C₃H₈ gas is exemplified as the C atom-containing gas, ethylene (hereinafter, referred to as “C₂H₄”) gas and acetylene (hereinafter, referred to as “C₂H₂”) gas may be used.

Further, a dopant gas may be further supplied from the gas supply port 60, or another gas supply port for supplying the dopant gas may be separately installed to supply the dopant gas.

Furthermore, the first exhaust port 62 is disposed opposite to the first supply port 60, and a gas exhaust pipe 76 connected to the first exhaust port 62 is installed at the manifold to pass therethrough.

As described above, since at least the Si atom-containing gas, the Cl atom-containing gas, the C atom-containing gas and the reduction gas are supplied from the first gas supply port 60 and the supplied gases flow in parallel with respect to the wafers 14 made of Si or SiC toward the first exhaust port 62, all the wafers 14 are effectively and uniformly exposed to the gases.

In addition, preferably, in the reaction chamber, a structure (not shown) may be installed between the object to be heated 46 and the wafers 14 or between the first gas supply port 60 and the first exhaust port 62. The structure may be formed of an insulating material or a carbon graphite material to resist heat or suppress generation of particles. Accordingly, the gases supplied from the first gas supply port 60 effectively and uniformly expose all the wafers 14, and uniformity of film thicknesses of SiC epitaxial films formed on the wafers 14 is improved.

The second gas supply port 64 is disposed between the reaction tube 42 and the insulating material 50 and installed to pass through the manifold. In addition, the second exhaust port 66 is disposed between the reaction tube 42 and the insulating material 50 to be opposite to the second gas supply port 64, and the gas exhaust pipe 76 connected to the second exhaust port 66 is installed at the manifold to pass therethrough. The second gas supply port 64, through which an inert gas such as argon (hereinafter, referred to as “Ar”) gas is supplied, can block intrusion of a gas that contributes to growth of the SiC epitaxial film, for example, the Si atom-containing gas, the C atom-containing gas or the Cl atom-containing gas, or a mixture thereof, between the reaction tube 42 and the insulating material 50, and prevent unnecessary byproducts from sticking to an inner wall of the reaction tube 42 or an outer wall of the insulating material 50.

In addition, a vacuum exhaust apparatus 80 such as a vacuum pump is connected to a downstream side of the gas exhaust pipe 76 via a pressure sensor as a pressure detector and an automatic pressure controller (hereinafter, referred to as “APC”) valve 78 as a pressure regulator, which are not shown. A pressure control unit (not shown) is electrically connected to the pressure sensor and the APC valve 78. The pressure control unit is configured to control a pressure at predetermined timings by adjusting an opening angle of the APC valve 78 according to the pressure detected by the pressure sensor such that the pressure inside the object to be heated 46 and the pressure in a space between the reaction tube 42 and the insulating material 50 reach a predetermined pressure.

Further, while the Ar gas is exemplified as the inert gas, the inert gas is not limited thereto but at least one gas from rare gases such as helium (hereinafter, referred to as “He”) gas, neon (hereinafter, referred to as “Ne”) gas, krypton (hereinafter, referred to as “Kr”) gas, and xenon (hereinafter, referred to as “Xe”), or a gas mixed with the at least one of the rare gases may be supplied.

Next, peripheral components of the processing furnace 40 will be described. A seal cap 82 as a lid body for a furnace port is installed under the processing furnace 40 to hermetically close a lower opening of the processing furnace 40. The seal cap 82 is made of, for example, a metal such as stainless steel, and has a circular disk shape. An O-ring as a seal material abutting a lower end of the processing furnace 40 is installed at an upper surface of the seal cap 82. A rotary mechanism 84 is installed at the seal cap 82. A rotary shaft of the rotary mechanism 84, which is coupled to the boat 30 through the seal cap 82, is configured to rotate the boat 30 and thus rotate the wafers 14. The seal cap 82 is configured to be vertically raised and lowered by a lift motor (not shown) as a lift mechanism disposed at an outside of the processing furnace 40, enabling loading and unloading of the boat 30 into/from the processing furnace 40. A driving control unit (not shown) is electrically connected to the rotary mechanism 84 and the lift motor and configured to control a predetermined operation at a predetermined timing.

Hereinafter, a method of forming a SiC epitaxial film on a substrate such as a wafer made of SiC will be described as one process of the semiconductor device manufacturing process using a semiconductor manufacturing apparatus 10 constituted as described above. Here, in the following description, operations of the components of the semiconductor manufacturing apparatus 10 are controlled by a controller (not shown).

First, when the pod 16 in which the plurality of wafers 14 are accommodated is set to the pod stage 18, the pod 16 is transferred from the pod stage 18 to the pod shelf 20 by the pod transfer apparatus 20 to be stocked on the pod shelf 22. Next, the pod 16 stocked on the pod shelf 22 is transferred to the pod opener 24 to be set by the pod transfer apparatus 20, the lid of the pod 16 is opened by the pod opener 24, and the number of wafers 14 accommodated in the pod 16 is detected by the substrate number detector 26.

Next, the wafers 14 are unloaded from the pod 16 disposed at the pod opener 24 and transferred to the boat 30 by the substrate transfer unit 28.

When the plurality of wafers 14 are charged into the boat 30, the boat 30 in which the plurality of wafers 14 are held is loaded into the reaction chamber 44 by a lift operation of a lift platform and a lift shaft (not shown) by the lift motor (boat loading). In this state, the seal cap 82 seals the lower end of the manifold via the O-ring.

The reaction chamber 44 is vacuum exhausted by the vacuum exhaust apparatus 80 such that the inside of the object to be heated 46 becomes a predetermined pressure (vacuum level). Here, the pressure in the object to be heated 46 is measured by the pressure sensor, and the APC valve 78 in communication with the first exhaust port 62 and the second exhaust port 66 is feedback-controlled according to the measured pressure. In addition, the wafers 14 and the inside of the object to be heated 46 are heated by the induction coil 48 as an induction heating source to a predetermined temperature, heating the object to be heated 46 and the wafers 14 as the substrates. Here, a conduction state to the induction coil 48 is feedback-controlled according to the temperature information detected by the temperature sensor such that the inside of the object to be heated 46 has a predetermined temperature distribution. Next, as the boat 30 is rotated by the rotary mechanism 84, the wafers 14 are rotated in a circumferential direction thereof.

Continuously, the Si atom-containing gas, the Cl atom-containing gas, the C atom-containing gas and the H₂ gas as the reduction gas, which contribute to the SiC epitaxial growth reaction, are supplied from the gas sources 70a, 70b, 70c and 70c, respectively, injected from the at least one first gas supply port 60, which is installed inside the object to be heated 46, into the object to be heated 46, and the SiC epitaxial growth reaction is performed.

At this time, the Si atom-containing gas, the Cl atom-containing gas, the C atom-containing gas and the H₂ gas as the reduction gas are supplied through the first gas line 68 from the first gas supply port 60 into the object to be heated 46, after the opening angles of the MFCs 72a, 72b, 72c and 72d are adjusted to correspond to a predetermined flow rate and then the valves 74a, 74b, 74c and 74c are opened.

The gases supplied from the first gas supply port 60 pass through the inside of the object to be heated 46 in the reaction chamber, and are exhausted from the first exhaust port 62 through the gas exhaust pipe 76. The supplied gases are supplied from side surfaces of the wafers 14 upon passing through the inside of the object to be heated 46, and contact the wafers 14 to perform the SiC epitaxial film growth on the surfaces of the wafers 14.

Then, the inert gas such as the Ar gas supplied from a gas supply source 70e is supplied from the second gas supply port 64 into the space formed between the reaction tube 42 and the insulating material 50 via the gas supply pipe to a predetermined flow rate after an opening angle of an MFC 72e is adjusted and a valve 74e is opened. The Ar gas as the insert gas supplied from the second gas supply port 64 passes through the space formed between the insulating material 50 and the reaction tube 42 in the reaction chamber 44, and is exhausted through the second exhaust port 66.

When a predetermined time for the SiC epitaxial film growth elapses, supply of the gases is stopped, and the inert gas is supplied from an inert gas supply source (not shown), the gases in the object to be heated 46 are substituted with the inert gas, and simultaneously, the pressure in the reaction chamber 44 is returned to a normal pressure.

Thereafter, the seal cap 82 is lowered by the lift motor to open the lower end of the manifold, the processed wafers 14 are unloaded from the lower end of the manifold to the outside of the reaction tube 42 with the wafers 14 held by the boat 30 (boat unloading), and the boat 30 is on standby at a predetermined position until all the wafers 14 held by the boat 30 are cooled. Next, when the wafers 14 on the boat 30 on standby are cooled to a predetermined temperature, the wafers 14 are taken out of the boat 30 by the substrate transfer unit 28, and transferred to the pod 16 in an empty state set by the pod opener 24 to be accommodated therein. Next, the pod transfer apparatus 20 transfers the pod 16, in which the wafers 14 are accommodated, to the pod shelf 22 or the pod stage 18. Therefore, a series of operations of the semiconductor manufacturing apparatus 10 is completed.

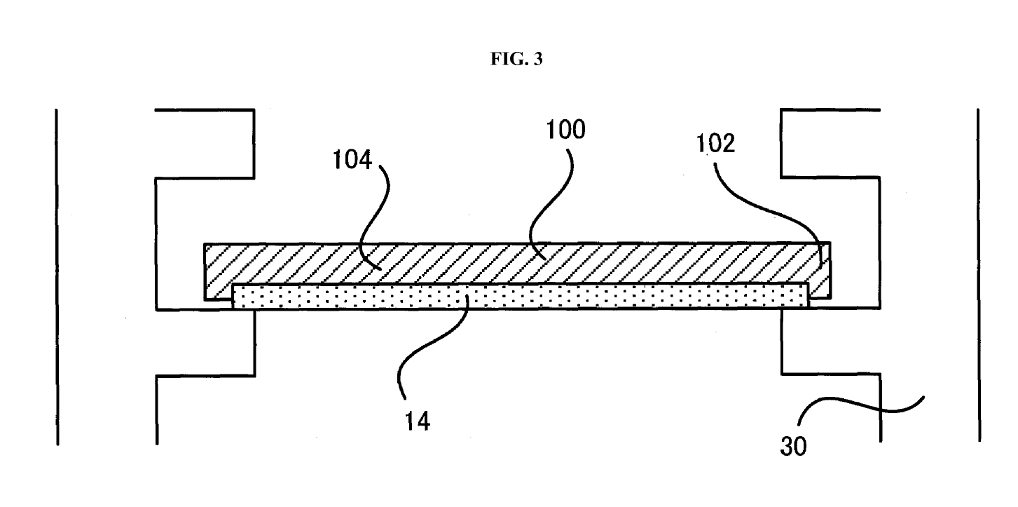

Hereinafter, the wafer 14 and the wafer holder in accordance with the first embodiment of the present invention will be described in detail with reference to FIG. 3. FIG. 3 is an enlarged view of the wafer 14 and the wafer holder in accordance with the first embodiment of the present invention.

The wafer holder in accordance with the first embodiment of the present invention is an upper wafer holder 100 having a substantially circular disk shape, and configured to cover a back surface (i.e. an upper surface shown in the drawing) of the wafer 14 supported by a post of the boat 30. The upper wafer holder 100 has an inner circumferential part 104 configured to cover the back surface of the wafer 14, and an outer circumferential part 102 thicker than the inner circumferential part 104. That is, the upper wafer holder 100 is configured to have a side cross-section with an inverted concave shape.

As shown in FIG. 3, a difference in thickness of the outer circumferential part 102 and the inner circumferential part 104 is designed to be smaller than a thickness of the wafer 14. That is, the upper wafer holder 100 is configured to be supported by the wafer 14 and contact the back surface of the wafer 14 at the inner circumferential part 104 thereof. Accordingly, all of the inner circumferential part 104 contacting the back surface of the wafer 14 forms “a gas introduction suppression part” on the back surface of the wafer 14 to remove a gap through which the gas is introduced. As described above, the inner circumferential part 104 as an example of the gas introduction suppression part in accordance with the present invention may be installed to suppress introduction of a reaction gas onto the back surface of the wafer 14, suppressing formation of the SiC film on the back surface of the wafer 14.

In the first embodiment of the present invention, a shape of the upper wafer holder 100 is not particularly limited, but the upper wafer holder 100 may have various shapes as long as the gas introduction suppression part installed to surround the wafer 14 may be provided to suppress introduction of the reaction gas onto the back surface of the wafer 14.

### Second Embodiment

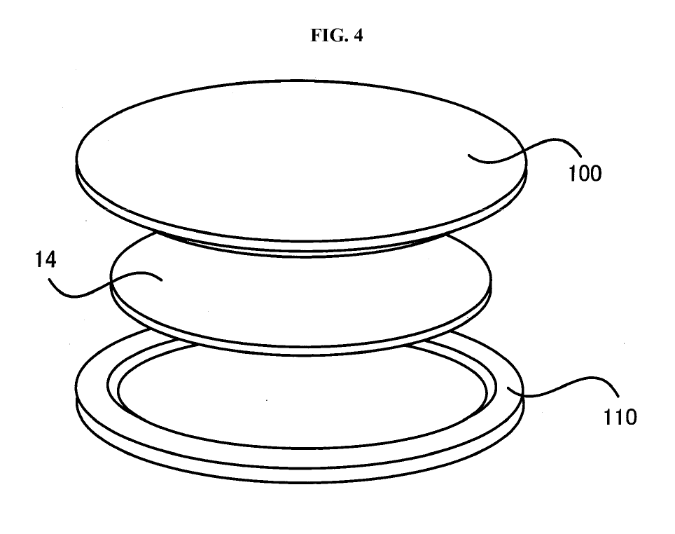

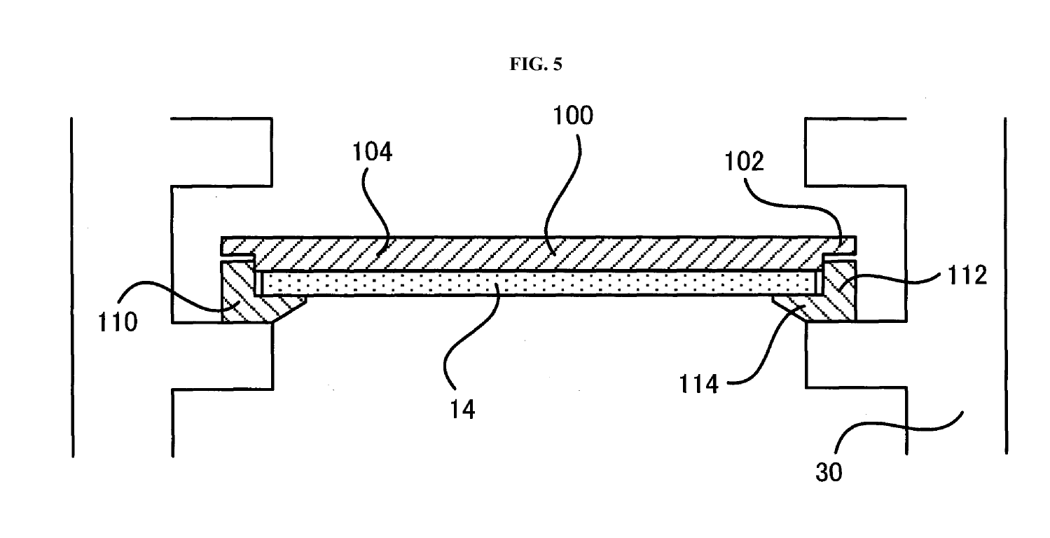

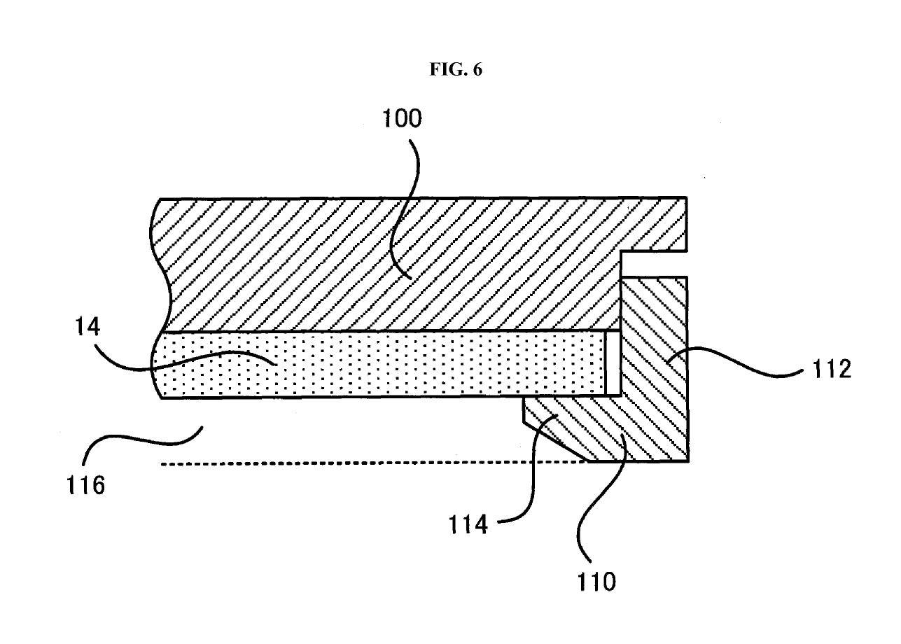

Hereinafter, the wafer holder in accordance with the second embodiment of the present invention will be described with reference to FIGS. 4 through 6. Here, FIG. 4 is an enlarged perspective view illustrating configuration of the wafer 14 and the wafer holder in accordance with the second embodiment of the present invention, FIG. 5 is an enlarged view of the wafer 14 and the wafer holder in accordance with the second embodiment of the present invention, and FIG. 6 is an enlarged view of a lower wafer holder in accordance with the second embodiment of the present invention. In addition, in FIGS. 4 through 6, like reference numerals refer to like elements in FIG. 3, and detailed description thereof will not be repeated.

While the wafer holder of the first embodiment is configured to include the upper wafer holder 100 only, as shown in FIGS. 4 and 5, the wafer holder of the second embodiment is configured to include an upper wafer holder 100 having a substantially circular disk shape formed to cover the back surface of the wafer 14, and a lower wafer holder 110 having a substantial ring shape formed to support the wafer 14 and simultaneously introduce the reaction gas onto a front surface (i.e., a lower surface shown in the drawing) of the wafer 14.

As shown in FIG. 5, the upper wafer holder 100 in accordance with the second embodiment is configured such that an outer circumferential part 102 is thinner than an inner circumferential part 104, i.e., to form a side cross-section with an inverted convex shape. The lower wafer holder 110 is configured such that an outer circumferential part 112 is thicker than an inner circumferential part 114, i.e., to form a side cross-section with a substantially concave shape.

Since the wafer holder in accordance with the second embodiment of the present invention includes the lower wafer holder 110, the arm (tweezers) 32 of the substrate ‘ 28 can hold the lower wafer holder 110 to transfer the wafer 14 to the boat 30 without contacting the wafer 14.

In addition, a difference in thickness of the outer circumferential part 112 and the inner circumferential part 114 of the lower wafer holder 110 and a difference in thickness of the outer circumferential part 102 and the inner circumferential part 104 of the upper wafer holder 100 may be smaller than the thickness of the wafer 14. That is, when the upper wafer holder 100 and the lower wafer holder 110 are assembled, the upper wafer holder 100 is supported by the wafer 14, and the inner circumferential part 104 (i.e., a projection directed downward in the drawing) contact the back surface of the wafer 14. Accordingly, all of the inner circumferential part 104 contacting the back surface of the wafer 14 forms “a gas introduction suppression part” on the back surface of the wafer 14 to remove a gap through which the gas is introduced. As described above, the inner circumferential part 104 as an example of the gas introduction suppression part in accordance with the present invention is installed to suppress introduction of the reaction gas onto the back surface of the wafer 14, suppressing formation of the SiC film on the back surface of the wafer 14.

In addition, when the upper wafer holder 100 and the lower wafer holder 110 are assembled, a front end (i.e., a lower surface of the projection directed downward in the drawing) of the inner circumferential part 104 of the upper wafer holder 100 may be configured to be disposed in a position lower than an upper end (i.e., an upper surface directed upward in the drawing) of the outer circumferential part 112 of the lower wafer holder 110. According to the configuration, even when the reaction gas is laterally injected, separation of the upper wafer holder 100 from the lower wafer holder 110 may be prevented. In particular, the SiC substrate is very slippery, which makes the configuration very effective. In addition, according to the configuration of the upper wafer holder 100 and the lower wafer holder 110 of the second embodiment, the entire thickness of the wafer holder is increased in comparison with the wafer holder in accordance with the first embodiment, but an overlapping range of the thicknesses may be freely designed, and separation of the upper wafer holder due to the laterally injected reaction gas may be prevented.

In the second embodiment of the present invention, a shape of the upper wafer holder 100 is not particularly limited, but the upper wafer holder 100 may have various shapes as long as the gas introduction suppression part installed to surround the wafer 14 may be provided to suppress introduction of the reaction gas onto the back surface of the wafer 14.

In addition, as shown in FIG. 6, a lower surface of the lower wafer holder 110 may be configured such that the thickness decreases toward a center portion 116 of the lower wafer holder 110. According to the above configuration, a flow of the laterally injected gas may be guided toward a film-forming surface (i.e., a lower surface shown in the drawing) of the wafer 14.

Further, a shape of the lower surface of the lower wafer holder 110 is not particularly limited, but the lower surface of the lower wafer holder 110 may have various shapes as long as the flow of the laterally injected gas may be guided toward the film-forming surface (i.e., the lower surface shown in the drawing) of the wafer 14. For example, as shown in FIG. 6, the lower surface of the lower wafer holder 110 is configured such that a thickness of only a lower surface of the inner circumferential part 114 of the lower wafer holder 110 decreases toward the center portion 116 of the lower wafer holder 110, but may be configured such that thicknesses of lower surfaces of both the outer circumferential part 112 and the inner circumferential parts 114 of the lower wafer holder 110 decrease toward the center portion 116 of the wafer holder 110.

### Third Embodiment

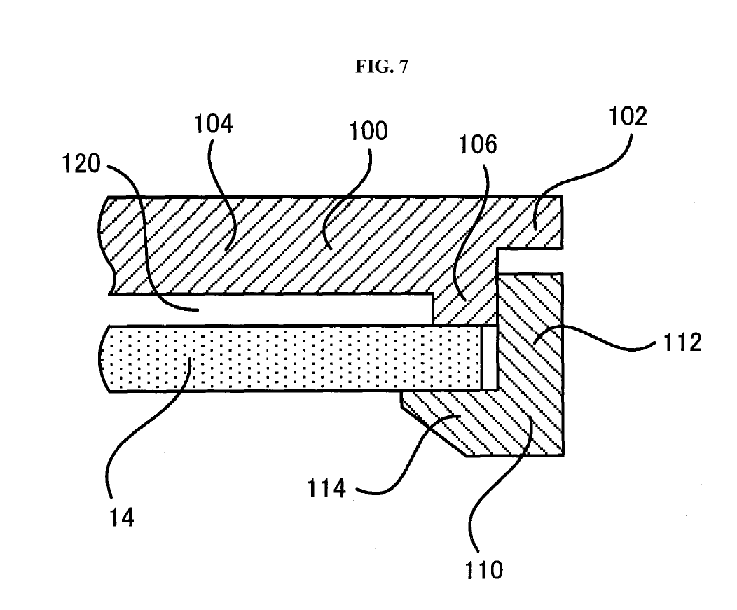

Hereinafter, the third embodiment of the present invention will be described with reference to FIG. 7. FIG. 7 is an enlarged view of the wafer 14 and the wafer holder in accordance with the third embodiment of the present invention. In FIG. 7, like reference numerals refer to like elements in FIG. 6, and detailed description thereof will not be repeated.

As a modified example of the second embodiment of the present invention, in the third embodiment, a ring-shaped projection 106 thicker than the outer circumferential part 102 of the upper wafer holder 100 and thicker than the center portion of the inner circumferential part 104 projects from an outer edge of the inner circumferential part 104 of the upper wafer holder 104. Accordingly, when the upper wafer holder 100 and the lower wafer holder 110 are assembled, the ring-shaped projection 106 may contact the back surface of the wafer 14 to suppress introduction of the reaction gas onto the back surface of the wafer 14, suppressing formation of the SiC film on the back surface of the wafer 14. Therefore, the ring-shaped projection 106 in contact with the back surface of the wafer 14 constitutes “the gas introduction suppression part.”

As described above, the ring-shaped projection 106 projects from the inner circumferential part 104 of the upper wafer holder 100 to form a hollow part 120 between the center portion of the inner circumferential part 104 of the upper wafer holder 100 and the back surface of the wafer 14. Accordingly, a contact area between the upper wafer holder 100 and the back surface of the wafer 14 is reduced. Therefore, contact of the wafer 14 with the upper wafer holder 100 may be suppressed.

Meanwhile, in the third embodiment of the present invention, while the hollow part 120 is formed between the inner circumferential part 104 of the upper wafer holder 100 and the back surface of the wafer 14, a shape of the upper wafer holder 104 is not particularly limited, but the upper wafer holder 104 may have various shapes as long as the gas introduction suppression part installed to surround the wafer 14 may be provided to suppress introduction of the reaction gas onto the back surface of the wafer 14. For example, the outer circumferential part 102 of the upper wafer holder 100 may contact the outer circumferential part 112 of the lower wafer holder 110 such that the inner circumferential part 104 of the upper wafer holder 100 is not in perfect contact with the back surface of the wafer 14, rather than projecting the projection 106 contacting the back surface of the above-described wafer 14 from the inner circumferential part 104 of the upper wafer holder 100.

In the third embodiment of the present invention, when the interior of the processing furnace 40 is vacuumed, an air may remain in the hollow part 120 and affect a time for evacuation to a vacuum level. For this reason, a vent port for the air may be provided in the hollow part. At this time, since formation of the vent port reduces an amount of the reaction gas reaching the back surface of the wafer 14 and a thickness of the film formed thereon, a time for an abrasion process may be reduced and thus the throughput may be improved. That is, as the hollow part 120 and the vent port are formed, the throughput of the film-forming process may be improved, and the vacuum level in vacuum film forming may be maintained as well.

[Supplementary Notes]

Hereinafter, preferred aspects of the embodiments will be additionally stated.

[Supplementary Note 1]

A wafer holder used in a film forming apparatus comprising a boat holding a plurality of wafers and a reaction gas supply part supplying a reaction gas from a side surface of the plurality of wafers held by the boat, the wafer holder comprising: an upper wafer holder being placed to cover an upper surface of each of the plurality of wafers when the plurality of wafer is supported by the boat and including a gas introduction suppression part suppressing an introduction of the reaction gas onto the upper surface of each the plurality of wafers by surrounding each of the plurality of wafers.

[Supplementary Note 2]

The wafer holder according to Supplementary Note 1, wherein the gas introduction suppression part is supported by each of the plurality of wafers.

[Supplementary Note 3]

The wafer holder according to Supplementary Note 2, wherein the upper wafer holder has a concave shape wherein an outer circumferential part of the upper wafer holder is thicker than an inner circumferential part thereof, a height from an upper surface of the inner circumferential part of the upper wafer holder to a front end surface of the outer circumferential part of the upper wafer holder is smaller than a thickness of each of the plurality of wafers, and the inner circumferential part of the upper wafer holder contacts each of the plurality of wafers to constitute the gas introduction suppression part.

[Supplementary Note 4]

The wafer holder according to Supplementary Note 2, further comprising a lower wafer holder holding each of the plurality of wafers, wherein the lower wafer holder is supported by the boat.

[Supplementary Note 5]

The wafer holder according to Supplementary Note 4, wherein the upper wafer holder has a convex shape wherein an outer circumferential part of the upper wafer holder is thinner than an inner circumferential part thereof, the lower wafer holder has a ring-shaped concave shape wherein an outer circumferential part of the lower wafer holder is thicker than an inner circumferential part thereof, and when the upper wafer holder and the lower wafer holder are assembled, a front end surface of the inner circumferential part of the upper wafer holder is disposed in a position lower than a front end surface of the outer circumferential part of the lower wafer holder.

[Supplementary Note 6]

The wafer holder according to Supplementary Note 5, wherein, when the upper wafer holder and the lower wafer holder are assembled, the front end surface of the inner circumferential part of the upper wafer holder contacts the upper surface of each of the plurality of wafers held by the lower wafer holder to constitute the gas introduction suppression part.

[Supplementary Note 7]

The wafer holder according to Supplementary Note 4, wherein a lower surface of the lower wafer holder is configured such that a thickness of the lower wafer holder decreases toward a center portion thereof.

[Supplementary Note 8]

The wafer holder according to Supplementary Note 4, wherein the upper wafer holder comprises a ring-shaped projection thicker than the outer circumferential part of the upper wafer holder and thicker than a center portion of the upper wafer holder, and when the upper wafer holder and the lower wafer holder are assembled, the ring-shaped projection contacts the upper surface of each of the plurality of wafers to constitute the gas introduction suppression part.

[Supplementary Note 9]

The wafer holder according to Supplementary Note 1, further comprising a lower wafer holder supported by the boat and holding the plurality of wafers, wherein an outer circumferential part of the upper wafer holder contacts an outer circumferential part of the lower wafer holder to constitute the gas introduction suppression part.

[Supplementary Note 10]

A film forming apparatus comprising:

a boat holding a plurality of wafer holders according to any one of Supplementary Notes 1 through 9, on which wafers to be processed are held; and

a reaction gas supply part supplying a reaction gas from side surfaces of the plurality of wafers held by the boat.

[Supplementary Note 11]

A film forming method comprising:

placing an upper wafer holder to cover an upper surface of a wafer, the upper wafer holder having a gas introduction suppression part suppressing an introduction of a reaction gas onto an upper surface of a wafer by surrounding the wafer;

transferring the wafer and the upper wafer holder to a boat with the upper wafer holder placed on the wafer;

loading the boat into a reaction chamber; and

supplying the reaction gas into the reaction chamber to form a film on a lower surface of the wafer.

The wafer holder and film forming method according to the present invention may be used in the wafer holder and film forming method used in the film forming apparatus for forming the SiC epitaxial film on the substrate.

What is claimed is:

1. A wafer holder used in a film forming apparatus comprising a boat holding a plurality of wafers and a reaction gas supply part supplying a reaction gas from a side surface of the plurality of wafers held by the boat, the wafer holder comprising:
an upper wafer holder being placed to cover an upper surface of each of the plurality of wafers when the plurality of wafer is supported by the boat and including a gas introduction suppression part suppressing an introduction of the reaction gas onto the upper surface of each the plurality of wafers by surrounding each of the plurality of wafers.

2. The wafer holder according to claim 1, wherein the gas introduction suppression part is supported by each of the plurality of wafers.

3. The wafer holder according to claim 2, wherein the upper wafer holder has a concave shape wherein an outer circumferential part of the upper wafer holder is thicker
a height from an upper surface of the inner circumferential part of the upper wafer holder to a front end surface of the outer circumferential part of the upper wafer holder is smaller than a thickness of each of the plurality of wafers, and
the inner circumferential part of the upper wafer holder contacts each of the plurality of wafers to constitute the gas introduction suppression part.

4. The wafer holder according to claim 2, further comprising a lower wafer holder holding each of the plurality of wafers, wherein the lower wafer holder is supported by the boat.

5. The wafer holder according to claim 4, wherein the upper wafer holder has a convex shape wherein an outer circumferential part of the upper wafer holder is thinner than an inner circumferential part thereof,
the lower wafer holder has a ring-shaped concave shape wherein an outer circumferential part of the lower wafer holder is thicker than an inner circumferential part thereof, and
when the upper wafer holder and the lower wafer holder are assembled, a front end surface of the inner circumferential part of the upper wafer holder is disposed in a position lower than a front end surface of the outer circumferential part of the lower wafer holder.

6. The wafer holder according to claim 5, wherein, when the upper wafer holder and the lower wafer holder are assembled, the front end surface of the inner circumferential part of the upper wafer holder contacts the upper surface of each of the plurality of wafers held by the lower wafer holder to constitute the gas introduction suppression part.

7. The wafer holder according to claim 4, wherein a lower surface of the lower wafer holder is configured such that a thickness of the lower wafer holder decreases toward a center portion thereof.

8. The wafer holder according to claim 4, wherein the upper wafer holder comprises a ring-shaped projection thicker than the outer circumferential part of the upper wafer holder and thicker than a center portion of the upper wafer holder, and when the upper wafer holder and the lower wafer holder are assembled, the ring-shaped projection contacts the upper surface of each of the plurality of wafers to constitute the gas introduction suppression part.

9. The wafer holder according to claim 1, further comprising a lower wafer holder supported by the boat and holding the plurality of wafers, wherein an outer circumferential part of the upper wafer holder contacts an outer circumferential part of the lower wafer holder to constitute the gas introduction suppression part.

10. A film forming apparatus comprising:
a boat holding a plurality of wafers;
a reaction gas supply part supplying a reaction gas from a side surface of the plurality of wafers held by the boat; and
an upper wafer holder being placed to cover an upper surface of each of the plurality of wafers when the plurality of wafer is supported by the boat and including a gas introduction suppression part suppressing an introduction of the reaction gas onto the upper surface of each of the plurality of wafers by surrounding each of the plurality of wafers.

11. The film forming apparatus according to claim 10, wherein the gas introduction suppression part is supported by each of the plurality of wafers.

12. The film forming apparatus according to claim 10, wherein the wafer holder further comprises a lower wafer holder holding the plurality of wafers, wherein the lower wafer holder is supported by the boat.

13. The film forming apparatus according to claim 12, wherein the upper wafer holder has a convex shape wherein an outer circumferential part of the upper wafer holder is thinner than an inner circumferential part of the upper wafer holder,
the lower wafer holder has a concave shape wherein an outer circumferential part of the lower wafer holder is thicker than an inner circumferential part thereof, and
when the upper wafer holder and the lower wafer holder are assembled, a front end surface of the inner circumferential part of the upper wafer holder is disposed in a position lower than a front end surface of the outer circumferential part of the lower wafer holder.

14. The film forming apparatus according to claim 13, wherein, when the upper wafer holder and the lower wafer holder are assembled, the front end surface of the inner circumferential part of the upper wafer holder contacts the upper surface of each of the plurality of wafers held by the lower wafer holder to constitute the gas introduction suppression part.

15. The film forming apparatus according to claim 12, wherein a lower surface of the lower wafer holder is configured such that a thickness of the lower wafer holder decreases toward a center portion thereof.

16. The film forming apparatus according to claim 12, wherein the upper wafer holder comprises a ring-shaped projection thicker than the outer circumferential part of the upper wafer holder and thicker than a center portion of the upper wafer holder, and when the upper wafer holder and the lower wafer holder are assembled, the ring-shaped projection contacts the upper surface of each of the plurality of wafers to constitute the gas introduction suppression part.

17. A film forming method comprising:
placing an upper wafer holder to cover an upper surface of a wafer, the upper wafer holder having a gas introduction suppression part suppressing an introduction of a reaction gas onto an upper surface of a wafer by surrounding the wafer;
transferring the wafer and the upper wafer holder to a boat with the upper wafer holder placed on the wafer;
loading the boat into a reaction chamber; and
supplying the reaction gas into the reaction chamber to form a film on a lower surface of the wafer.
